(19) United States
(12) Patent Application Publication
(10) Pub. No.: US 2015/0273535 A1
(43) Pub. Date: Oct. 1, 2015

(54) SUBSTRATE PROCESSING APPARATUS AND SUBSTRATE PROCESSING METHOD

(71) Applicant: Kabushiki Kaisha Toshiba, Minato-ku (JP)

(72) Inventors: Katsuhiro Sato, Yokkaichi (JP); Hideaki Hirabayashi, Yokohama (JP)

(73) Assignee: Kabushiki Kaisha Toshiba, Minato-ku (JP)

(21) Appl. No.: 14/632,302

(22) Filed: Feb. 26, 2015

(30) Foreign Application Priority Data
Mar. 25, 2014 (JP) 2014-061435

(51) Int. Cl. B08B 3/10; H01L 21/02

(52) U.S. Cl. CPC B08B 3/10; H01L 21/02041

(57) ABSTRACT

According to one embodiment, a substrate processing apparatus includes a first processor and a second processor. The first processor causes an amount of a solvent at a front surface of a substrate to decrease after supplying a first liquid to the front surface. The first liquid includes the solvent and a substance. The substance is transformable from a solid phase to a vapor phase. An unevenness pattern is provided in the front surface. The second processor includes a first processing chamber. The first processing chamber contains the substrate having the decreased amount of the solvent at the front surface. The first processing chamber removes the substance by causing at least a portion of the substance at the front surface to transform from the solid phase to the vapor phase by heating the substrate in a state in which an interior of the first processing chamber is depressurized.

### CROSS-REFERENCE TO RELATED APPLICATION

This application is based upon and claims the benefit of priority from Japanese Patent Application No. 2014-061435, filed on Mar. 25, 2014; the entire contents of which are incorporated herein by reference.

### FIELD

Embodiments described herein relate generally to a substrate processing apparatus and a substrate processing method.

### BACKGROUND

For example, a substrate is cleaned in the manufacturing processes of a semiconductor device. There are cases where a fine unevenness pattern is provided in the front surface of the substrate. There are cases where deformation (e.g., collapse) of the unevenness pattern occurs in the cleaning.

### BRIEF DESCRIPTION OF THE DRAWINGS

FIG. 1 is a schematic view showing a portion of a substrate processing apparatus according to a first embodiment;

FIG. 2 is a schematic view showing a portion of the substrate processing apparatus according to the first embodiment;

FIG. 3 is a schematic view showing a portion of the substrate processing apparatus according to the first embodiment;

FIG. 4 is a schematic view showing a portion of the substrate processing apparatus according to the first embodiment;

FIG. 5A to FIG. 5D are schematic views showing a substrate according to the first embodiment;

FIG. 6A and FIG. 6B are schematic views showing a portion of the substrate processing apparatus according to the first embodiment;

FIG. 7 is a schematic view showing a portion of a substrate processing apparatus according to a second embodiment;

FIG. 8 is a schematic view showing a portion of a substrate processing apparatus according to a third embodiment;

FIG. 9 shows the processing of the substrate processing apparatus according to the embodiment;

FIG. 10A to FIG. 10C are schematic views showing states of the substrate; and

FIG. 11 is a flowchart showing the operations of the substrate processing apparatus according to the embodiment.

15

### DETAILED DESCRIPTION

According to one embodiment, a substrate processing apparatus includes a first processor and a second processor. The first processor causes an amount of a solvent at a front surface of a substrate to decrease after supplying a first liquid to the front surface. The first liquid includes the solvent and a substance. The substance is transformable from a solid phase to a vapor phase. An unevenness pattern is provided in the front surface. The second processor includes a first processing chamber. The first processing chamber contains the substrate having the decreased amount of the solvent at the front surface. The first processing chamber removes the substance by causing at least a portion of the substance at the front surface to transform from the solid phase to the vapor phase by heating the substrate in a state in which an interior of the first processing chamber is depressurized.

Embodiments of the invention will now be described with reference to the drawings.

The drawings are schematic or conceptual; and the relationships between the thicknesses and widths of portions, the proportions of sizes between portions, etc., are not necessarily the same as the actual values thereof. Also, the dimensions and/or the proportions may be illustrated differently between the drawings, even in the case where the same portion is illustrated.

In the drawings and the specification of the application, components similar to those described in regard to a drawing thereinabove are marked with like reference numerals, and a detailed description is omitted as appropriate.

### First Embodiment

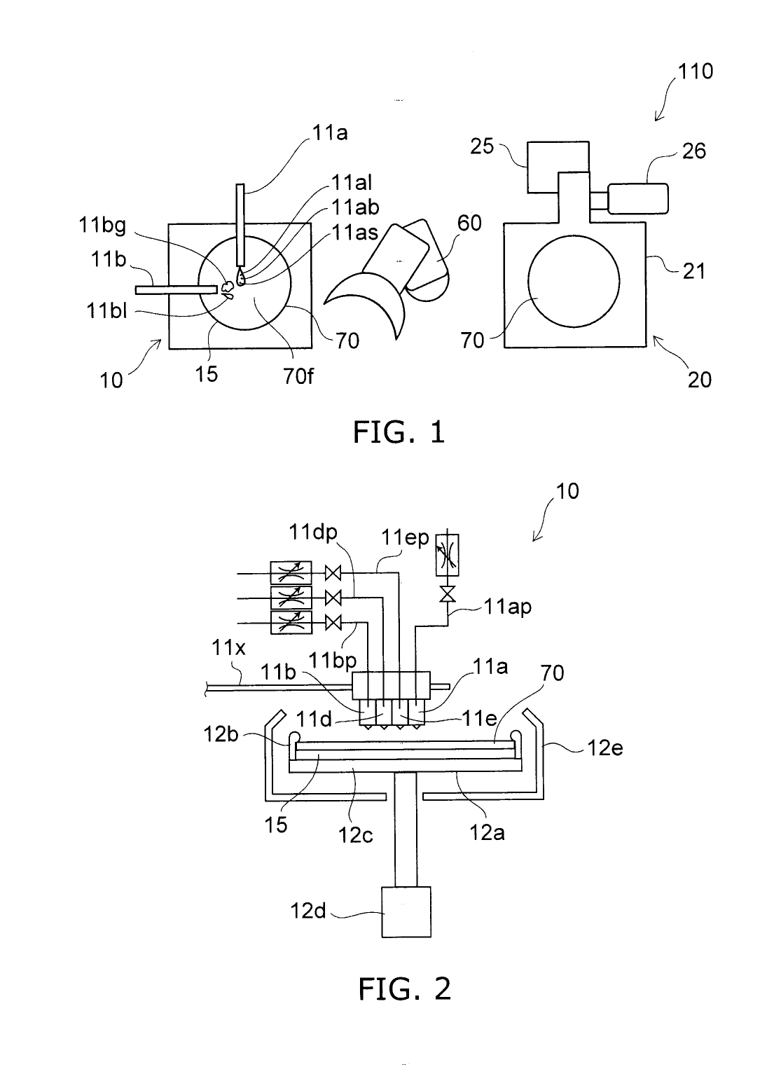

FIG. 1 is a schematic view showing a portion of a substrate processing apparatus according to a first embodiment.

As shown in FIG. 1, the substrate processing apparatus 110 according to the embodiment includes a first processor 10, a second processor 20, and a substrate transfer mechanism 60.

The first processor 10 includes, for example, a first supply unit 11a.

The first supply unit 11a supplies, for example, a first liquid 11al to a front surface 70f of a substrate 70. The first liquid 11al includes, for example, a solvent 11ab and a substance 11as that is directly transformable from a solid to a vapor phase. The substance 11as is, for example, sublimable. For example, a semiconductor wafer is used as the substrate 70.

In the example, a second supply unit 11b is further provided in the first processor 10. For example, the second supply unit 11b supplies a second liquid 11bl to the front surface 70f of the substrate 70. The second liquid 11bl includes, for example, at least one of a rinsing liquid (water or purified water) or a cleaning chemical liquid such as SC1 liquid (a mixed liquid of ammonia and aqueous hydrogen peroxide), DHF (dilute hydrofluoric acid), SC2 liquid (a mixed liquid of hydrochloric acid and aqueous hydrogen peroxide), SPM (a mixture of sulfuric acid and aqueous hydrogen peroxide), etc. For example, the second supply unit 11b may supply a gas 11bg toward the front surface 70f.

The first processor 10 further includes a first heater 15. The first heater 15 causes the temperature of the substrate 70 supplied with the first liquid 11al to increase. In other words, a first heating is implemented. The first heater 15 causes the amount of the solvent at the front surface 70f of the substrate 70 to decrease. The solvent is caused to volatilize. As described below, for example, the second supply unit 11b may be used to cause the amount of the solvent to decrease.

The second processor 20 includes a first processing chamber 21. The first processing chamber 21 contains the substrate 70. The first processing chamber 21 causes the temperature of the substrate 70 to increase in a state in which the interior of the first processing chamber 21 is depressurized. In other words, heating (a second heating) is implemented at reduced pressure. Thereby, the substance 11as is removed by causing at least a portion of the substance 11as recited above at the front surface 70f of the substrate 70 to directly transform from the solid phase to the vapor phase.

In the example, the substrate processing apparatus 110 includes, for example, a depressurizing pump 25 (e.g., a vacuum pump) and an intermediate unit 26 (e.g., a collection mechanism). For example, the depressurizing pump 25 is connected to the second processor 20 (the first processing chamber 21). The depressurizing pump 25 depressurizes the interior of the first processing chamber 21. The intermediate unit 26 is provided between the second processor 20 (the first processing chamber 21) and the depressurizing pump 25. For example, the intermediate unit 26 collects the substance 11as that has directly transformed from the solid phase to the vapor phase.

The substrate transfer mechanism 60 transfers the substrate 70 between the first processor 10 and the second processor 20.

FIG. 2 is a schematic view showing a portion of the substrate processing apparatus according to the first embodiment.

FIG. 2 shows the first processor 10.

As shown in FIG. 2, the first processor 10 includes a first holder 12a. The first holder 12a holds the substrate 70 to be substantially horizontal and rotates the substrate 70. The first holder 12a includes a holding member 12b that holds a side surface 70s of the substrate 70, a spin chuck 12c (e.g., a rotation mechanism) that holds a back surface 70r of the substrate 70, and a rotation drive unit 12d that rotates the spin chuck 12c.

A cup 12e is provided around the first holder 12a. For example, the cup 12e receives the liquid (the first liquid 11al, the second liquid 11bl, etc.) scattering from the substrate 70. For example, the first holder 12a and the cup 12e move in the vertical direction. The substrate 70 is movable between the first holder 12a and the substrate transfer mechanism 60.

In the example, the first heater 15 is provided in the first holder 12a. The first heater 15 is a substrate heating unit that heats the substrate 70.

In the example, for example, a first pipe line 11ap is connected to the first supply unit 11a. The first pipe line 11ap includes, for example, a flow rate adjuster and an open/close valve. For example, the first pipe line 11ap supplies the first liquid 11al to the first supply unit 11a.

In the example, a second pipe line 11bp is connected to the second supply unit 11b. The second pipe line 11bp includes, for example, a flow rate adjuster and an open/close valve. For example, the second pipe line 11bp supplies a second liquid 11bl to the second supply unit 11b. The number of second supply units 11b is arbitrary.

In the example, an arm 11x is provided in the first processor 10. For example, the arm 11x is substantially parallel to the front surface 70f of the substrate 70. The first supply unit 11a and the second supply unit 11b are fixed to the arm 11x. The arm 11x is opposable to multiple portions of the front surface 70f of the substrate 70. Thereby, the first supply unit 11a and the second supply unit 11b are opposable to the multiple portions of the front surface 70f of the substrate 70.

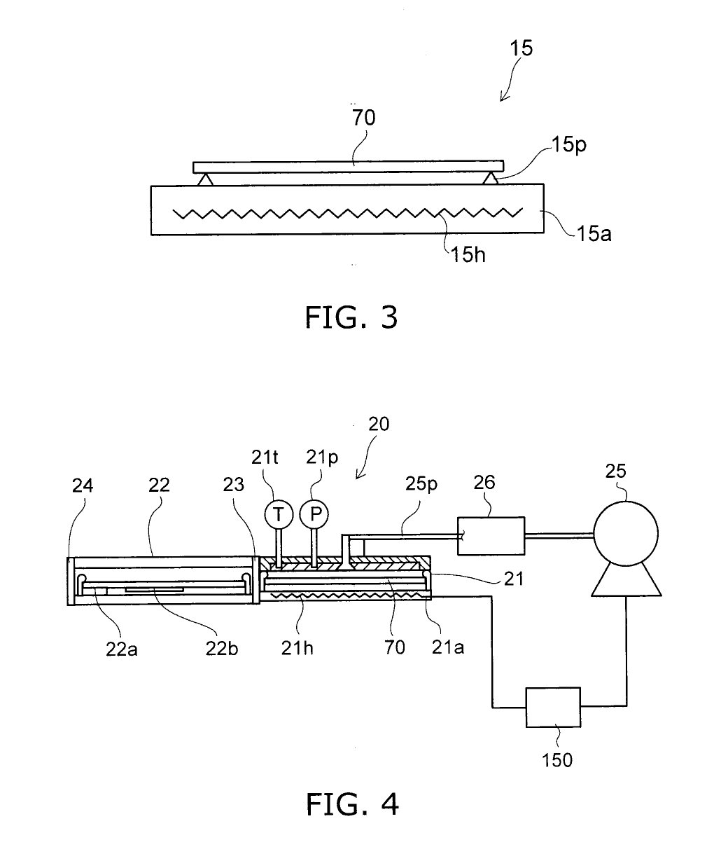

FIG. 3 is a schematic view showing a portion of the substrate processing apparatus according to the first embodiment.

As shown in FIG. 3, the first heater 15 includes, for example, a heat plate 15a. For example, a heater 15h for heating (e.g., a hotplate) is provided in the interior of the heat plate 15a. Multiple holder pins 15p are provided at the front surface of the heat plate 15a. The holder pins 15p hold the back surface 70r of the substrate 70. A small gap is made between the heat plate 15a and the back surface 70r of the substrate 70.

FIG. 4 is a schematic view showing a portion of the substrate processing apparatus according to the first embodiment.

In the example as shown in FIG. 4, a second processing chamber 22 is provided in the second processor 20. A first shutter 23 (e.g., a door) is provided between the first processing chamber 21 and the second processing chamber 22. The first shutter 23 is openable and closable.

The first processing chamber 21 includes a first substrate holder 21a, a second heater 21h (e.g., a heating mechanism), a pressure gauge 21p, and a temperature gauge 21t. For example, the first substrate holder 21a holds the substrate 70 to be substantially horizontal. For example, the second heater 21h is provided at one of a lower portion, side portion, or upper portion of the first processing chamber 21. In the example, the second heater 21h is provided at the lower portion of the first processing chamber 21. The pressure gauge 21p senses the pressure of the interior of the first processing chamber 21. The temperature gauge 21t senses the temperature of the interior of the first processing chamber 21. For example, an infrared heater (e.g., a halogen heater, a carbon heater, etc.) is used as the second heater 21h. The reduced-pressure atmosphere when heating the first processing chamber 21 is, for example, less than the atmospheric pressure. It is desirable for the reduced-pressure atmosphere to be about 0.1 Pa; and it is desirable for the heating temperature to be not less than 30° C. and not more than 300° C.

For example, a controller 150 is provided in the substrate processing apparatus 110. The controller 150 includes, for example, a pressure controller, a depressurization rate adjuster, a temperature controller, an atmosphere controller, a transfer time controller, etc. The controller 150 controls the pressure of the interior of the first processing chamber 21 and the temperature of the substrate 70 contained in the first processing chamber 21. For example, the controller 150 heats the substrate 70 contained in the first processing chamber 21 after depressurizing the interior of the first processing chamber 21.

The substrate processing apparatus 110 includes, for example, depressurization piping 25p. The depressurization piping 25p is provided between the first processing chamber 21 and the depressurizing pump 25.

The second processing chamber 22 includes a second shutter 24, a second substrate holder 22a, and a substrate transfer arm 22b. For example, the second shutter 24 makes possible the transfer of the substrate 70 between the substrate transfer mechanism 60 and the second processing chamber 22. The second substrate holder 22a holds the substrate 70. For example, the substrate transfer arm 22b moves the substrate from the second processing chamber 22 to the first processing chamber 21. The substrate transfer arm 22b may be provided in the first processing chamber 21. For example, the second substrate holder 22a holds multiple substrates 70 when the multiple substrates 70 are processed simultaneously (batch processing). The substrate transfer arm 22b moves the second substrate holder 22a holding the multiple substrates 70 to the first processing chamber 21.

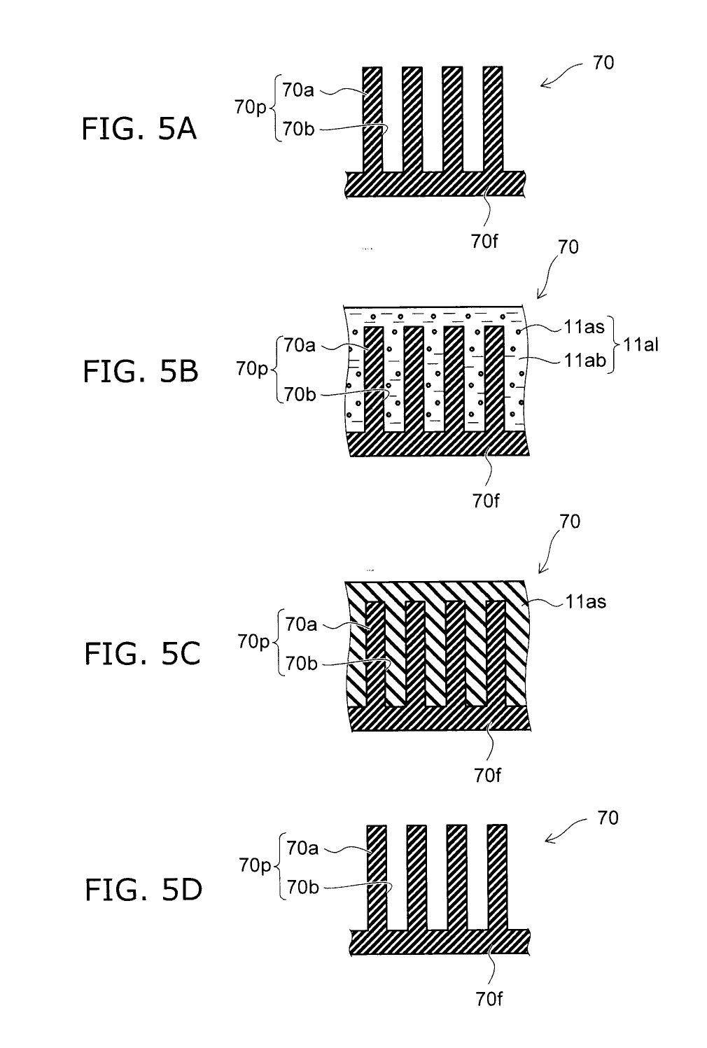

FIG. 5A to FIG. 5D are schematic views showing a substrate according to the first embodiment.

As shown in FIG. 5A, protrusions 70a and recesses 70b are provided in the front surface 70f of the substrate 70. In other words, an unevenness pattern 70p is provided.

FIG. 5B shows the front surface 70f of the substrate 70 after the first liquid 11al is supplied. For example, the front surface 70f of the substrate 70 is covered with the first liquid 11al. In other words, the unevenness pattern 70p is covered with the first liquid 11al.

FIG. 5C shows the front surface 70f of the substrate 70 after the first heating. For example, the front surface 70f of the substrate 70 is covered with the substance 11as. In other words, the solvent volatilizes due to the first heating (drying). Thereby, a state is formed in which the unevenness pattern 70p is covered with the substance 11as.

FIG. 5D shows the front surface 70f of the substrate 70 after the second heating. The substance 11as changes from the solid phase to the vapor phase due to the second heating. The substance 11as is removed. At this time, the configuration of the unevenness pattern 70p is maintained at the front surface 70f of the substrate 70.

According to the embodiment, the substance 11as can be removed efficiently by performing the second heating inside the reduced-pressure atmosphere.

For example, in a reference example in which the second heating is performed in ambient air, for example, the substance 11as that has been transformed to the vapor phase by the heating collects easily in the recesses 70b of the unevenness pattern 70p. There are cases where the removal of the substance 11as is insufficient.

Conversely, in the embodiment, the substance 11as in the vapor phase is removed efficiently from the recesses 70b by implementing the second heating inside the reduced-pressure atmosphere. The removal of the substance 11as is implemented efficiently. Thereby, as shown in FIG. 5D, the configuration of the unevenness pattern 70p is maintained after the substance 11as is removed. Thus, according to the embodiment, a substrate processing apparatus in which deformation of the unevenness pattern 70p is suppressed can be provided.

In other words, the substrate processing apparatus 110 according to the embodiment includes the first processor 10 and the second processor 20. The first processor 10 causes the amount of the solvent 11ab at the front surface 70f to decrease after supplying the first liquid 11al to the front surface 70f of the substrate 70. The first liquid 11al includes the substance 11as and the solvent 11ab. The substance 11as is directly transformable from the solid phase to the vapor phase. The front surface 70f of the substrate 70 includes the unevenness pattern 70p.

The second processor 20 includes the first processing chamber 21. The first processing chamber 21 contains the substrate 70 having the decreased amount of the solvent 11ab. The first processing chamber 21 removes the substance 11as by causing at least a portion of the substance 11as at the front surface 70f to directly transform from the solid phase to the vapor phase by heating the substrate 70 in the state in which the interior of the first processing chamber 21 is depressurized.

Thereby, the deformation of the unevenness pattern 70p can be suppressed.

The controller 150 controls the pressure of the interior of the first processing chamber 21 and the temperature of the substrate 70 contained in the first processing chamber 21. For example, in the second heating, the controller 150 causes the temperature of the substrate 70 to increase after depressurizing the interior of the first processing chamber 21. The controller 150 sets the temperature of the substrate 70 to 80° C. or more after setting the pressure of the interior of the first processing chamber 21 to 3000 pascals or less.

In other words, the second processor 20 further includes the second processing chamber 22. The interior of the second processing chamber 22 is depressurized after the second processing chamber 22 contains the substrate 70 having the decreased amount of the solvent 11ab of the front surface 70f.

In the case where the second processing chamber 22 is provided, the substrate 70 inside the second processing chamber 22 having the depressurized interior is moved to the first processing chamber 21 having the depressurized interior.

The second processor 20 includes the first shutter 23 provided between the first processing chamber 21 and the second processing chamber 22. The first shutter 23 isolates the first processing chamber 21 from the second processing chamber 22 when modifying the air pressure of the interior of the second processing chamber 22. The first shutter 23 causes the second processing chamber 22 and the first processing chamber 21 to be continuous when moving the substrate 70 from inside the second processing chamber 22 having the depressurized interior to the first processing chamber 21 having the depressurized interior.

The pressure of the interior of the first processing chamber 21 in the second heating is not less than 0.1 pascals and not more than 3000 pascals. The temperature of the substrate 70 in the second heating is not less than 80° C. and not more than 250° C.

For example, the second heater 21h is provided inside the first processing chamber 21. Thereby, the substrate 70 is heated in the second heating. In the second heating, the second heater 21h is positioned in at least one of a position under the substrate 70, a position on the substrate 70, a position at a side of the substrate 70, or a position oblique to the substrate 70.

The second processor 20 includes the depressurizing pump 25 and the intermediate unit 26. The intermediate unit 26 is provided between the depressurizing pump 25 and the first processing chamber 21. The intermediate unit 26 is connected airtightly to the depressurizing pump 25 and the first processing chamber 21. The temperature of the intermediate unit 26 is lower than the temperature of the inner surface of the first processing chamber 21 in the second heating.

The intermediate unit 26 collects the substance 11as that has directly transformed from the solid phase to the vapor phase. The negative effects of the substance 11as on the depressurizing pump 25 are suppressed by the substance 11as being trapped. The operations of the depressurizing pump 25 are stable. Stable processing can be implemented.

In the example shown in FIG. 2, the first supply unit 11a supplies the first liquid 11al to the front surface 70f of the substrate 70 disposed on the first heater 15.

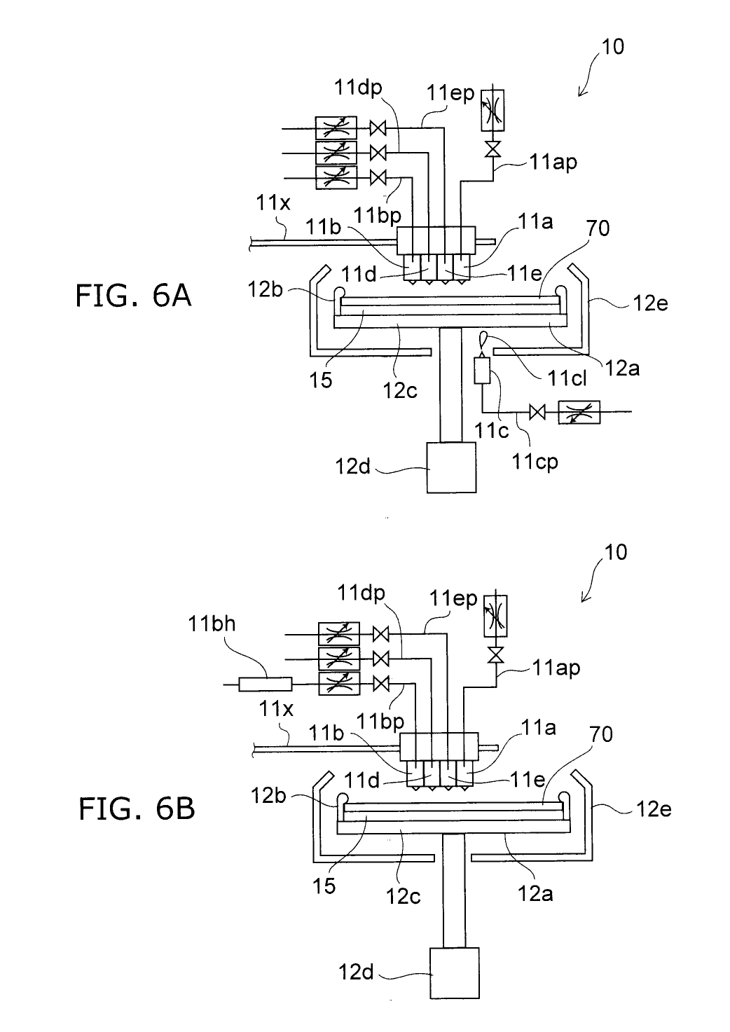

FIG. 6A and FIG. 6B are schematic views showing a portion of the substrate processing apparatus according to the first embodiment.

A third supply unit 11c is provided in the first processor 10 as shown in FIG. 6A. The third supply unit 11c supplies a third liquid 11cl to the back surface 70r of the substrate 70. For example, heated water is used as the third liquid 11cl. For example, by using the third liquid 11cl, the removal of the solvent 11ab from the first liquid 11al supplied to the front surface 70f of the substrate 70 is performed effectively. Thereby, the precipitation of the substance 11as is performed effectively.

A heater 11bh (a heating unit) is provided in the first processor 10 as shown in FIG. 6B. The heater 11bh is connected to the second supply unit 11b. The heater 11bh heats the gas 11bg. For example, the solvent 11ab is removed efficiently by the gas 11bg from the first liquid 11al supplied to the front surface 70f of the substrate 70. The precipitation of the substance 11as is performed efficiently.

### Second Embodiment

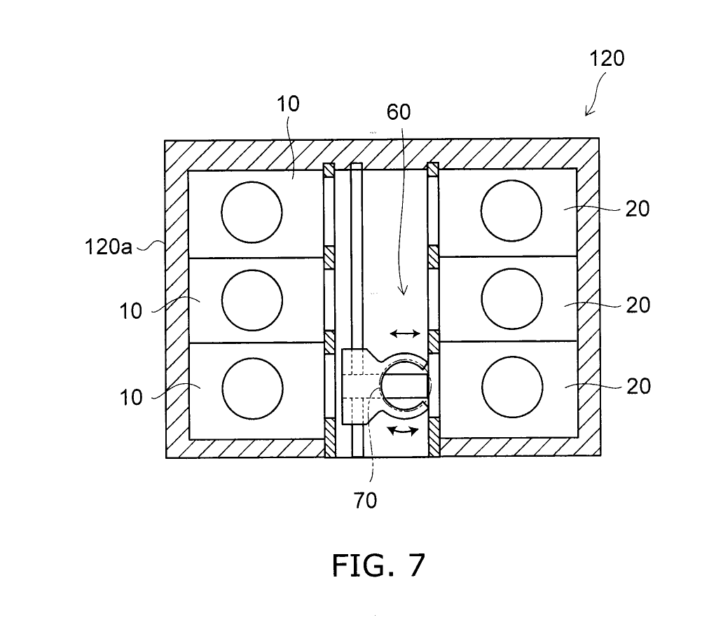

FIG. 7 is a schematic view showing a portion of a substrate processing apparatus according to a second embodiment.

As shown in FIG. 7, the substrate processing apparatus 120 according to the embodiment includes the first processor 10, the second processor 20, and the substrate transfer mechanism 60. The substrate transfer mechanism 60 is provided between the first processor 10 and the second processor 20.

For example, a substrate receiver/dispatcher is provided in the substrate processing apparatus 120. The substrate receiver/dispatcher moves the substrate 70 out of the substrate processing apparatus 120. The substrate receiver/dispatcher includes, for example, a carrier holder, a transfer part, and a delivery part. A carrier that contains the multiple substrates 70 is provided in the carrier holder. A transfer mechanism is provided in the transfer part. A delivery unit is provided in the delivery part. The transfer mechanism dispatches the substrate 70 from the carrier. The transfer mechanism transfers the substrate 70 to the delivery unit.

In the example as well, the substrate 70 is heated in a depressurized state in the first processing chamber 21 of the second processor 20. Thereby, the substance 11as is removed by causing at least a portion of the substance 11as to directly transform from the solid phase to the vapor phase. The substance 11as can be removed sufficiently. The deformation of the unevenness pattern 70p is suppressed.

### Third Embodiment

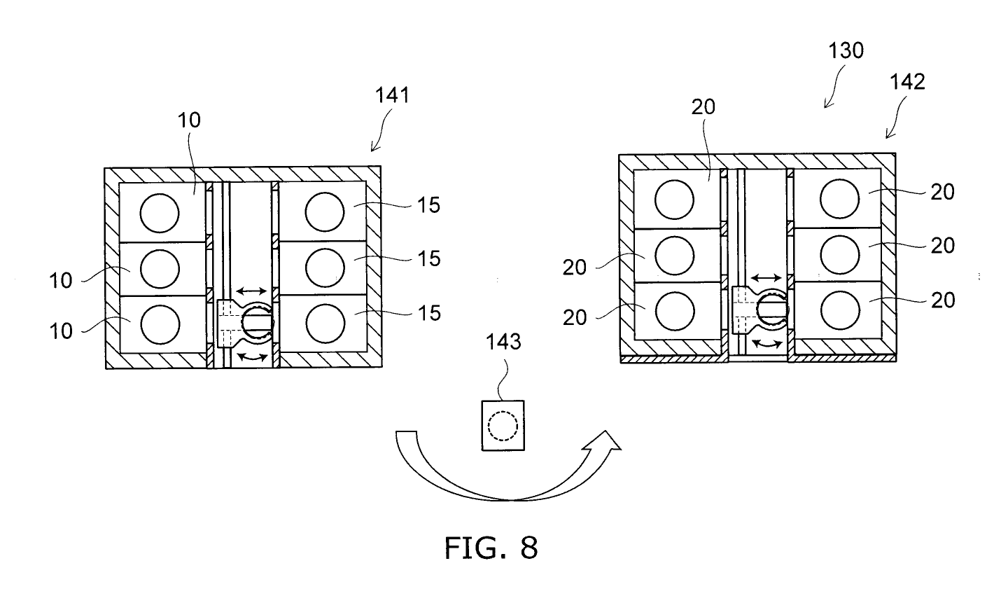

FIG. 8 is a schematic view showing a portion of a substrate processing apparatus according to a third embodiment.

As shown in FIG. 8, a substrate processing system 130 according to the embodiment includes a first cleaning apparatus 141, a second cleaning apparatus 142, and a transfer box (e.g., a FOSB) 143. The first cleaning apparatus 141 includes the first processor 10, the first heater 15, and the substrate transfer mechanism 60. The second cleaning apparatus 142 includes the second processor 20 and the substrate transfer mechanism 60. The transfer box 143 contains the substrate 70. The substrate processing system 130 moves the transfer box 143 in which the substrate 70 is contained between the first cleaning apparatus 141 and the second cleaning apparatus 142. The number of first processors 10, the number of second processors 20, and the number of first heaters 15 are arbitrary.

The first holder 12a that holds the substrate 70 is provided in the substrate processing system 130. The first supply unit 11a supplies the first liquid 11al to the front surface 70f of the substrate 70 held by the first holder 12a. The first heater 15 causes the temperature of the substrate 70 to increase at a position different from that of the first holder 12a.

In the example as well, the substrate 70 is heated in a depressurized state. The substance 11as can be removed sufficiently. The deformation of the unevenness pattern 70p is suppressed.

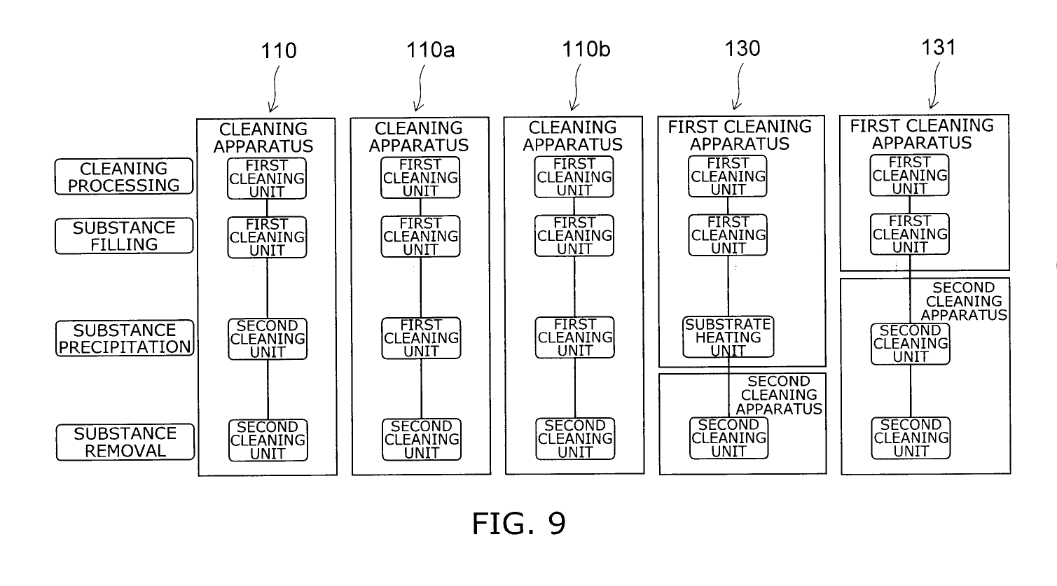

FIG. 9 shows the processing of the substrate processing apparatus according to the embodiment.

The substrate processing apparatus 110 implements the cleaning and the substance filling by the first processor 10 shown in FIG. 2. At least a portion of the substance precipitation may be implemented by the second processor 20. The substance removal is implemented by the second processor 20.

A substrate processing apparatus 110a implements the cleaning, the substance filling, and the substance precipitation by the first processor 10 shown in FIG. 6A. The substrate processing apparatus 110a implements the substance removal by the second processor 20.

A substrate processing apparatus 110b implements the cleaning, the substance filling, and the substance precipitation by the first processor 10 shown in FIG. 6B. The substrate processing apparatus 110b implements the substance removal by the second processor 20.

The substrate processing system 130 implements the cleaning, the substance filling, and the substance precipitation by the first processor 10 shown in FIG. 2. The substrate processing system 130 implements the substance removal by the second processor 20.

In a substrate processing system 131, the cleaning and the substance filling are implemented by the first processor 10 shown in FIG. 2. At least a portion of the substance precipitation may be implemented by the second processor. The substance removal is implemented by the second processor 20.

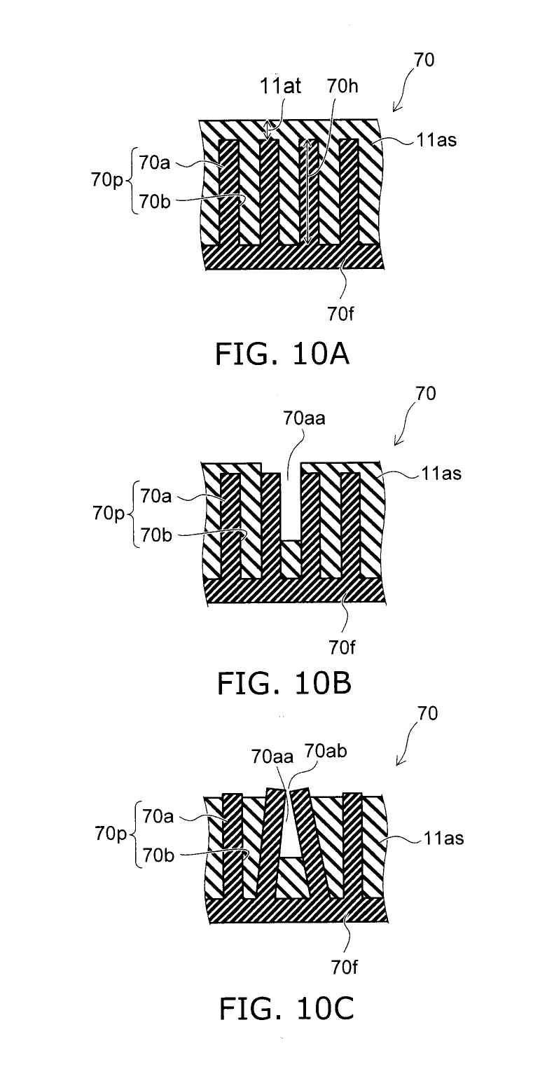

FIG. 10A to FIG. 10C are schematic views showing states of the substrate.

FIG. 10A shows a first example of the front surface 70f of the substrate 70 after the first heating. The protrusions 70a and the recesses 70b are provided in the front surface 70f of the substrate 70. The front surface 70f of the substrate 70 is covered with the substance 11as.

It is desirable for the distance (a thickness 11at) between the uppermost end of the protrusion 70a and the uppermost end of the substance 11as to be not less than 5% and not more than 20% of a height 70h of the protrusion 70a. In the case where the thickness 11at is thicker than 20% of the height 70h of the protrusion 70a, for example, the pattern collapses easily due to the stress of the substance 11as when removing the substance 11as.

FIG. 10B shows a second example of the front surface 70f of the substrate 70 after the first heating. The thickness 11at is thinner than 5% of the height 70h of the protrusion 70a. In such a case, an exposed region 70aa occurs at a portion of the protrusion 70a. Portions that are not covered with the substance 11as occur in the unevenness pattern 70p.

FIG. 10C shows the front surface 70f of the substrate 70 after the second heating in the second example. In the second example in which the unevenness pattern 70p is not sufficiently covered with the substance 11as, a collapsed portion 70ab occurs at the protrusion 70a at the front surface 70f of the substrate 70. In other words, the collapsed portion 70ab occurs when implementing the second heating in the case where the exposed region 70aa exists. The unevenness pattern 70p collapses in the exposed region 70aa.

Therefore, in the embodiment, the unevenness pattern 70p is covered with the substance 11as.

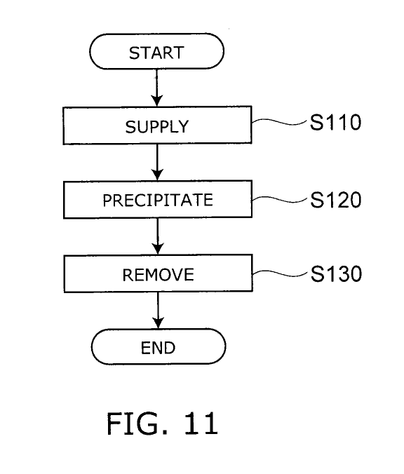

FIG. 11 is a flowchart showing the operations of the substrate processing apparatus according to the embodiment.

In the substrate processing apparatus 110 as shown in FIG. 11, for example, the first liquid 11al that includes the solvent 11ab and the substance 11as that is directly transformable from the solid phase to the vapor phase is supplied to the front surface 70f of the substrate 70 in which the unevenness pattern 70p is provided (step S110). For example, this operation is implemented by the first processor 10.

Then, the amount of the solvent 11ab of the front surface 70f is caused to decrease by implementing the first heating that causes the temperature of the substrate 70 supplied with the first liquid 11al to increase (step S120). For example, this operation is implemented by the first processor 10. A portion of step S120 may be implemented by the second processor 20.

The substance 11as is removed by causing at least a portion of the substance 11as at the front surface 70f to directly transform from the solid phase to the vapor phase by implementing the second heating that causes the temperature of the substrate 70 to increase in the state in which the interior of the first processing chamber 21 is depressurized (step S130). For example, this operation is implemented by the first processing chamber 21 of the second processor 20.

In the embodiment, for example, dry etching is performed for the substrate 70 that is processed. For example, a pattern is formed in a film (e.g., a SiN film) used as a portion of the semiconductor device by dry etching. The substrate transfer mechanism 60 moves the substrate 70 to the first processor 10. The spin chuck 12c holds the substrate 70 to be substantially horizontal. The rotation drive unit 12d rotates the substrate 70. For example, the second supply unit 11b supplies the second liquid 11bl to the center of the substrate 70. Etching residue, particles, etc., are removed from the front surface 70f of the substrate 70 by the second liquid 11bl. In other words, the cleaning is performed.

The rotation drive unit 12d maintains the substrate 70 in the rotating state. For example, a fourth supply unit 11d supplies a fourth liquid (e.g., water) 11dl to the center of the substrate 70. The second liquid 11bl and the particles (including the etching residue) at the front surface 70f of the substrate 70 are removed by the fourth liquid 11dl. In other words, the rinse of the cleaning processing is implemented.

Collapse of the unevenness pattern 70p of the substrate 70 occurs when the drying processing such as spin drying, etc., is performed in the state in which the fourth liquid 11dl is supplied to the front surface 70f of the substrate 70. Therefore, the first supply unit 11a supplies the first liquid 11al to the center of the substrate 70 prior to the drying. The fourth liquid 11dl at the front surface 70f of the substrate 70, etc., is removed by the first liquid 11al. The unevenness pattern 70p is covered with the first liquid 11al. In other words, substance filling (a first liquid supply) is implemented.

In the embodiment, the first liquid 11al is supplied to the front surface 70f of the substrate 70 prior to the removal of the fourth liquid 11dl. Thereby, the efficiency of the first liquid 11al removing the fourth liquid 11dl increases.

The thickness of the first liquid 11al at the front surface 70f of the substrate 70 is adjusted by the rotational speed of the substrate 70.

For example, the timing of the supply overlaps for the first liquid 11al, the second liquid 11bl, and the fourth liquid 11dl. Thereby, the drying of the front surface 70f of the substrate 70 can be suppressed.

After the first liquid 11al is supplied to the front surface 70f of the substrate 70, the amount of the solvent 11ab included in the first liquid 11al is caused to decrease. Thereby, the substance 11as is precipitated at the front surface 70f of the substrate 70. In other words, a substance precipitation (a first heating) is implemented.

The precipitation of the substance 11as may be implemented by various methods. For example, the amount of the solvent 11ab is caused to decrease by using the gas 11bg dispensed from the second supply unit 11b. The gas 11bg is supplied toward the substrate 70 in a state in which the substrate 70 is rotated. For example, the temperature of the gas 11bg is not less than room temperature; and the gas 11bg is heated.

For example, the amount of the solvent 11ab is caused to decrease by using the third liquid 11cl supplied from the third supply unit 11c. The third liquid 11cl is supplied to the back surface 70r of the substrate 70 from the third supply unit 11c in the state in which the substrate 70 is rotated. The temperature of the third liquid 11cl is, for example, not less than 40° C. and not more than 80° C.

For example, the amount of the solvent 11ab is caused to decrease by heating the substrate 70 using the first heater 15. The substrate transfer mechanism 60 moves the substrate 70 from the first processor 10 to the first heater 15. The substrate 70 is held using the holder pins 15p. The first heater 15 heats the substrate 70. The temperature of the substrate 70 is, for example, not less than 30° C. and not more than 150° C.

The solvent 11ab at the front surface 70f of the substrate 70 is removed by the methods recited above, etc.

For example, the transfer box 143 extracts the substrate 70 from the first cleaning apparatus 141. Subsequently, the transfer box 143 moves the substrate 70 to the second cleaning apparatus 142. Subsequently, the substrate transfer mechanism 60 moves the substrate 70 to the second processor 20. The substrate 70 that is introduced is transferred to the second processing chamber 22. Subsequently, the substrate transfer arm 22b moves the substrate 70 from the second processing chamber 22 to the first processing chamber 21. The first substrate holder 21a holds the substrate 70. The second heater 21h heats the substrate 70.

After the substance has is precipitated at the front surface 70f of the substrate 70, the substance 11as is removed (e.g., a substance removal (the second heating)). The substrate 70 that is processed by the first processor 10 is introduced to the second processing chamber 22. After depressurizing the interior of the second processing chamber 22, the first shutter 23 is opened; and the substrate 70 is introduced to the first processing chamber 21. The first processing chamber 21 is heated and depressurized beforehand. The second heater 21h heats the substrate 70 in the reduced-pressure atmosphere. It is desirable for the pressure of the interior of the first processing chamber 21 in the heating to be in the range of 3000 Pa to 0.1 Pa. It is desirable for the temperature of the substrate 70 in the heating to be in the range of 80° C. to 250° C.

For example, the second processor 20 performs the precipitation of the substance 11as. In such a case, the heating of the substrate 70 is implemented inside the first processing chamber 21. Subsequently, the interior of the first processing chamber 21 is depressurized. The second heater 21h heats the substrate 70 in a reduced-pressure atmosphere. The heating unit of the second heater 21h is arbitrary. The heating unit of the second heater 21h is, for example, a heating unit using radiant heat, etc. By the description recited above, collapse after cleaning a fine unevenness pattern can be suppressed.

For example, in the manufacturing processes of the semiconductor device, a fine unevenness pattern is formed in the front surface 70f of the substrate 70 by film formation, lithography, etching, etc. Cleaning processing using water or an organic solvent is performed in the process of forming the unevenness pattern 70p. The spacing of the unevenness pattern 70p (line-and-space) is becoming narrow. In a fine pattern having a spacing of 40 nm or less, the protrusions 70a are deformed by capillary force when the water remaining in the recesses 70b is dried from the substrate 70. Thereby, there are cases where mutually-adjacent protrusions 70a contact each other. In other words, the pattern collapses.

Although there is a method for replacing the rinsing liquid existing at the front surface 70f of the substrate 70 with IPA (isopropyl alcohol) after the cleaning processing to suppress the collapse of the fine unevenness pattern 70p, the effect of suppressing the collapse is insufficient for high aspect ratios.

On the other hand, a method may be considered in which a solution is filled into the recesses 70b by coating on the front surface 70f of the substrate 70 after the cleaning and coagulating by cooling or solvent removal; and subsequently, the coated substance is removed from the front surface 70f of the substrate 70 by heating at atmospheric pressure. For example, a solution including a polymer is supplied to the substrate 70 in which the unevenness pattern 70p is formed after the cleaning; and drying is performed. Subsequently, processing of at least one of heat treatment, depressurization, plasma processing, or reactant gas supply is performed to remove the polymer. Thereby, the polymer is decomposed and removed. However, in this method, there are cases where decomposition reactants remain at the front surface 70f of the substrate 70.

Conversely, in the embodiment, the unevenness pattern 70p is covered with the substance 11as that is directly transformable from the solid phase to the vapor phase. Then, the substance has is removed efficiently by performing the second heating inside the reduced-pressure atmosphere. The collection of the substance 11as in the vapor phase in the recesses 70b of the unevenness pattern 70p can be suppressed; and the substance 11as in the vapor phase is removed efficiently from the recesses 70b. In the embodiment, the decomposition reactants substantially are not produced. Even in the case where the decomposition reactants are produced, the decomposition reactants are evacuated efficiently.

Thus, there are cases where the capillary force acts in the unevenness pattern 70p and pattern collapse occurs in the cleaning of the substrate 70 having the unevenness pattern 70p in the front surface 70f. The substrate processing apparatus 110 according to the embodiment suppresses the pattern collapse in the cleaning of the substrate 70 having such an unevenness pattern 70p.

The embodiment relates to a substrate cleaning system (an apparatus) that dries a substrate having an unevenness pattern formed in the front surface by removing the liquid on the substrate. A first cleaning unit that includes a cleaning liquid supply unit supplying the cleaning liquid to the substrate surface and a solution supply unit supplying a solution including a sublimable substance to the substrate surface is provided. A second cleaning unit that includes a housing chamber containing the substrate, a unit that heats the substrate contained in the housing chamber, and a unit that depressurizes the substrate contained in the housing chamber is further provided.

For example, the substrate cleaning system according to the embodiment performs processing to clean the front surface of the substrate with the cleaning liquid and dry the cleaned substrate. The substrate cleaning system includes the first cleaning unit and the second cleaning unit. The first cleaning unit includes the cleaning liquid supply unit and the solution supply unit. The cleaning liquid supply unit supplies the cleaning liquid to the substrate surface. The solution supply unit supplies the solution including a sublimable substance to the substrate surface. The second cleaning unit includes the housing chamber, the unit that heats, and the unit that depressurizes. The housing chamber contains the substrate. The heating unit heats the substrate contained in the housing chamber. The depressurizing unit depressurizes the substrate contained in the housing chamber.

The first cleaning unit includes a unit that causes the precipitation. The precipitating unit causes the sublimable substance to precipitate from the solution.

The first cleaning unit includes a holding mechanism, a rotation mechanism, a first nozzle, and a second nozzle. In the holding mechanism, the first cleaning unit holds the substrate to be horizontal. The rotation mechanism rotates the substrate in a horizontal plane. The first nozzle is opposable to the major surface of the substrate at a prescribed spacing from the major surface. The first nozzle supplies a cleaning liquid or a rinsing liquid to the substrate. The second nozzle is opposable to the major surface of the substrate at a prescribed spacing from the major surface. The second nozzle supplies a solution including an organic solvent or a sublimable substance to the substrate.

The second cleaning unit includes a control mechanism, a depressurization rate adjustment mechanism, and a temperature control mechanism. The control mechanism controls the pressure inside the housing chamber. The depressurization rate adjustment mechanism adjusts the depressurization rate inside the housing chamber. The temperature control mechanism controls the temperature inside the housing chamber.

The substrate cleaning system includes an atmosphere control mechanism and a transfer time control mechanism.

The atmosphere control mechanism transfers the substrate between the first cleaning unit and the second cleaning unit and controls the atmosphere of the substrate. The transfer time control mechanism controls the transfer time.

The second cleaning unit includes a collection mechanism and a control unit. The collection mechanism collects the sublimable substance inside the housing chamber. The control unit controls the temperature of the collection mechanism to be lower than the wall surface temperature of the housing chamber.

The unit that causes the sublimable substance to precipitate includes at least one heating mechanism of a mechanism that supplies purified water, a mechanism that heats from the back surface of the substrate, a mechanism that supplies gas to the substrate, or a mechanism that heats the substrate. Purified water that is heated to not less than room temperature is supplied from the back surface of the substrate by the mechanism that supplies purified water. The mechanism that heats from the back surface of the substrate heats from the back surface of the substrate by a hotplate. The mechanism that supplies gas to the substrate supplies gas heated to not less than room temperature to the substrate. The mechanism that heats the substrate heats the substrate in a heating chamber heated to not less than room temperature.

For example, the substrate processing apparatus according to the embodiment cleans the front surface of the substrate using a cleaning liquid and dries the cleaned substrate.

The substrate processing apparatus includes the processing chamber, the cleaning liquid supply unit, the solution supply unit, the unit that causes the sublimable substance to precipitate, the removal chamber that removes the sublimable substance, the unit that heats the substrate, the unit that depressurizes, and the transfer unit. The processing chamber contains the substrate and performs cleaning processing. The cleaning liquid supply unit supplies a cleaning liquid to the substrate surface contained in the processing chamber. The solution supply unit supplies a solution including a sublimable substance to the substrate surface contained in the processing chamber. The unit that causes the sublimable substance to precipitate causes the sublimable substance to precipitate from the solution. The removal chamber is sealable and removes the sublimable substance. The unit that heats the substrate heats the substrate contained in the removal chamber. The removal chamber is depressurized by the unit that depressurizes. The transfer unit transfers the substrate between the processing chamber and the removal chamber.

The substrate processing apparatus includes an atmosphere control unit. The atmosphere control unit controls the atmosphere of the substrate to be an inert atmosphere or a dry atmosphere in the transferring and/or inside the removal chamber.

The removal chamber includes a depressurization rate adjustment unit. The depressurization rate adjustment unit adjusts the depressurization rate.

The removal chamber includes a holding mechanism and a rotation mechanism. The holding mechanism holds the substrate to be horizontal. The rotation mechanism rotates the substrate on the horizontal plane.

The removal chamber includes a collection unit and a control unit. The collection unit communicates with the removal chamber and collects the sublimable substance. The control unit controls the temperature of the collection unit to be lower than the wall surface temperature of the removal chamber. The removal chamber includes a substrate holding unit and an exhaust port. The substrate holding unit is capable of containing multiple substrates.

According to the embodiments, a substrate processing apparatus and a substrate processing method in which deformation of the unevenness pattern is suppressed are provided.

Hereinabove, embodiments of the invention are described with reference to specific examples. However, the invention is not limited to these specific examples. For example, one skilled in the art may similarly practice the invention by appropriately selecting specific configurations of components included in the substrate processing apparatus such as the first processor, the second processor, the supply unit, the processing chamber, etc., from known art; and such practice is within the scope of the invention to the extent that similar effects can be obtained.

Further, any two or more components of the specific examples may be combined within the extent of technical feasibility and are included in the scope of the invention to the extent that the purport of the invention is included.

Moreover, all substrate processing apparatus practicable by an appropriate design modification by one skilled in the art based on the substrate processing apparatus described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A substrate processing apparatus, comprising:
a first processor causing an amount of a solvent at a front surface of a substrate to decrease after supplying a first liquid to the front surface, the first liquid including the solvent and a substance, the substance being transformable from a solid phase to a vapor phase, an unevenness pattern being provided in the front surface; and
a second processor including a first processing chamber, the first processing chamber containing the substrate having the decreased amount of the solvent at the front surface, the first processing chamber removing the substance by causing at least a portion of the substance at the front surface to transform from the solid phase to the vapor phase by heating the substrate in a state in which an interior of the first processing chamber is depressurized.

2. The apparatus according to claim 1, further comprising a controller controlling a pressure of the interior of the first processing chamber and a temperature of the substrate contained in the first processing chamber,
the controller causing, in the heating, the temperature of the substrate to increase after the interior of the first processing chamber is depressurized.

3. The apparatus according to claim 2, wherein the controller sets the temperature of the substrate to 80° C. or more after setting the pressure of the interior of the first processing chamber to 3000 pascals or less.

4. The apparatus according to claim 1, wherein
the second processor further includes a second processing chamber,
an interior of the second processing chamber is depressurized in a state in which the second processing chamber contains the substrate having the decreased amount of the solvent at the front surface, and
the second processor moves the substrate from inside the second processing chamber having the depressurized interior to the first processing chamber having the depressurized interior.

5. The apparatus according to claim 4, wherein
the second processor further includes a first shutter provided between the first processing chamber and the second processing chamber,
the first shutter isolates the first processing chamber from the second processing chamber when modifying an air pressure of the interior of the second processing chamber, and
the first shutter causes the second processing chamber and the first processing chamber to be continuous when moving the substrate from inside the second processing chamber having the depressurized interior to the first processing chamber having the depressurized interior.

6. The apparatus according to claim 1, wherein a pressure of the interior of the first processing chamber in the heating is not less than 0.1 pascals and not more than 3000 pascals.

7. The apparatus according to claim 1, wherein a temperature of the substrate in the heating is not less than 80° C. and not more than 250° C.

8. The apparatus according to claim 1, wherein
the second processor further includes:
a depressurizing pump; and
an intermediate unit provided between the depressurizing pump and the first processing chamber and connected airtightly to the depressurizing pump and the first processing chamber, and
a temperature of the intermediate unit is lower than a temperature of an inner surface of the first processing chamber in the heating.

9. The apparatus according to claim 8, wherein the intermediate unit collects the substance transformed from the solid phase to the vapor phase.

10. The apparatus according to claim 1, wherein
the first processor includes:
a first supply unit supplying the first liquid to the front surface; and
a first heater heating the substrate supplied with the first liquid, and
the first supply unit supplies the first liquid to the front surface of the substrate disposed on the first heater.

11. The apparatus according to claim 1, wherein
the first processor includes:
a first supply unit supplying the first liquid to the front surface;
a first heater heating the substrate supplied with the first liquid; and
a first holder holding the substrate,
the first supply unit supplies the first liquid to the front surface of the substrate held by the first holder, and
the first heater causes a temperature of the substrate to increase at a position different from a position of the first holder.

12. The apparatus according to claim 11, wherein the temperature of the substrate heated in the first heater is not less than 30° C. and not more than 150° C.

13. The apparatus according to claim 11, wherein the first holder rotates the substrate.

14. The apparatus according to claim 1, wherein
the first processor includes:
a heater heating a gas; and
a second supply unit supplying the gas heated by the heater to the front surface of the substrate.

15. The apparatus according to claim 1, wherein the first processor includes a third supply unit supplying a third liquid to a back surface of the substrate.

16. The apparatus according to claim 15, wherein a temperature of the third liquid is not less than 40° C. and not more than 80° C.

17. The apparatus according to claim 1, wherein
the second processor includes a heater provided inside the first processing chamber, the heater causing a temperature of the substrate to increase, and
the heater is positioned in at least one of a position under the substrate, a position on the substrate, a position at a side of the substrate, or a position oblique to the substrate.

18. The apparatus according to claim 17, wherein a heating temperature of the heater is not less than 30° C. and not more than 300° C.

19. The apparatus according to claim 17, wherein a temperature of the substrate heated in the heater is not less than 80° C. and not more than 250° C.

20. A substrate processing method, comprising:
causing an amount of a solvent at a front surface of a substrate to decrease after supplying a first liquid to the front surface, the first liquid including the solvent and a substance, the substance being transformable from a solid phase to a vapor phase, an unevenness pattern being provided in the front surface; and
removing the substance by causing at least a portion of the substance at the front surface to transform from the solid phase to the vapor phase by heating the substrate inside a depressurized space, the substrate having the decreased amount of the solvent at the front surface.
